(19) United States
(12) Patent Application Publication
(10) Pub. No.: US 2002/0125479 A1
(43) Pub. Date: Sep. 12, 2002

(54) MOSFET and method of its fabrication

(76) Inventors: Gunther Lippert, Frankfurt/Oder (DE); Abbas Ourmazd, Berlin (DE); Hans-Joerg Osten, Muellrose (DE)

Correspondence Address: Law Offices of Karl Hormann, 86 Sparks Street, Cambridge, MA, 02138-2216, US

(21) Appl. No.: 10/011,698

(22) Filed: Nov. 5, 2001

Related U.S. Application Data
(63) Continuation-in-part of application No. 09/319,643, filed on Jun. 9, 1999.
Application No. 09/319,643 is a 371 of international application No. PCT/DE97/02911, filed on Dec. 8, 1997.

(30) Foreign Application Priority Data
Dec. 9, 1996 (DE) 196 52 417.2

(51) Int. Cl. H01L 29/04

(52) U.S. Cl. 257/64; 257/627; 257/628; 438/150

(57) ABSTRACT

The invention relates to a MOSFET with a doped silicon source layer and a doped polycrystalline silicon gate layer and a doped silicon drain layer and to a method of fabricating the layers of such a transistors, in which an otherwise possible interaction between closely spaced layers or structural components of decreased size is eliminated or at least substantially reduced by incorporation in at least one layer of the MOSFET of an element from Group IV in a predetermined concentration.

### CROSS-REFERENCE TO RELATED APPLICATION

This is a continuation-in-part of Application No. 09/319,643 filed Jun. 9, 1999.

### BACKGROUND OF THE INVENTION

1. Field of the Invention

The invention relates to a MOSFET with a doped silicon source layer, a doped polycrystalline silicon gate layer and a doped silicon drain layer, and to a method of fabricating the layers of such a transistor with a doped silicon source layer, a doped polycrystalline silicon gate layer and a doped silicon drain layer.

In the fabrication of semiconductors, the sizes of the structural components and, more particularly, the spatial separation of structures electrically operating in different ways are reduced with increasing integration density. Between such structures, interactions occur as a result of the small spaces which interactions should be avoided for the sake of proper transistor function. By the use of very thin gate oxides, flat pn junctions or short channel lengths, the diffusion of charges can significantly affect properties relevant to the components.

2. The Prior Art

The literature (Eaglesham, Stolk, Gossmann, Poate in Appl. Phys. Lett., Vol. 65, (1994), p. 2305), describes that silicon defects caused by the implantation of silicon also affect the outdiffusion of dopants. The outdiffusion of the dopant, e.g. boron, may be reduced by executing the necessary annealing in an argon atmosphere rather than in a hydrogen atmosphere (Saito et al. In Appl. Phys. Lett., Vol. 68 (1996), p. 1229). However, this requires accepting the elimination of the positive effects of hydrogen annealing, such as surface cleaning.

German laid-open patent specification DE 43 01 333 A1 describes a method of fabricating, and at the same time doping, integrated silicon germanium hetero bipolar transistors in which a collector layer, as base layer, an emitter layer and an emitter connection layer are precipitated by a single uninterrupted process. This method of fabricating transistors suitable for high frequency applications suffers from the drawback that a further increase in the doping of the base with foreign atoms would lead to an outdiffusion of dopants at the relevant temperature which is to say that the base region would be broadened. On the one hand, dopant outdiffusion results in a non-uniform fabrication of transistors and, on the other hand, in an increase of the base resistance. Hence, it is not possible in this fashion to improve the suitability of transistors for high frequency applications.

European patent application EP 0,568,108 discloses prevention of the outdiffusion of dopants by an additional metal nitride barrier. This, however, involves additional measures and complex process steps in the fabrication of components.

European patent application EP 0,532,361 discloses the fabrication of semiconductors which is to prevent interdiffusion of dopant in adjacent structural elements by fabrication of an insulating trench, among others. In this case, too, a higher integration density involves additional complex process steps for the multiple step fabrication of the insulating trench. Moreover, further development of individual transistors is limited by the outdiffusion of dopant from gate, drain and source.

U.S. Pat. No. 5,514,902 describes a MOSFET wherein a material from the group of nitrogen, fluorine, argon, oxygen or carbon is incorporated in the source, drain and gate layers to prevent the outdiffusion of boron.

In U.S. Pat. No. 5,189,504 a MOS structure is described which is provided with a B or C doped polycrystalline silicon gate.

EP 0,717,435 A1 describes a method of controlling the outdiffusion of dopant in semiconductor layers.

In DE 44 30 366 A1 EP there are described a semiconductor device and a method of its fabrication.

### OBJECTS OF THE INVENTION

It is an object of the invention to provide a MOSFET which overcomes the mentioned disadvantages of the prior art and in which, compared to a conventional MOSFET, outdiffusion of dopant from the base region is reduced by more than 50%.

It is a further object of the invention to set up conventional methods of fabricating the individual layers of such a MOSFET such that the usual limitations and complex requirements in respect of follow-up processes, in particular the limitations as regards the levels of implantation doses and temperature-time stress, are reduced.

A particular object of the invention is to insure that MOSFETs produced in the manner herein set forth have a reduced starting voltage, channels of reduced length and/or a reduced noise level, depending upon requirements and intended application.

### SUMMARY OF THE INVENTION

In accordance with the invention the objects are accomplished by the addition of an electrically inert material, preferably an element from group IV, being incorporated in at least one of the layers of the transistor, in particular in the source layer and/or the gate layer and/or the drain layer of a MOSFET of the kind provided with a doped silicon source layer, a doped polycrystalline silicon gate layer and a doped silicon drain layer, in a concentration between 10¹⁸ cm⁻³ and 10⁻²¹ cm⁻³ with the thus introduced relative change in the lattice constant being less than 5·10⁻³.

In accordance with the invention, carbon is used as the electrically inert material. One or more layers of the transistor, namely the polycrystalline silicon gate layer, the silicon source layer and the silicon drain layer, are doped with boron, the concentration of the dopant being between 10²⁰ cm⁻³ and 10²¹ cm⁻³ and the concentration of carbon being between 10¹⁸ cm⁻³ and 10²¹ cm⁻³.

The method in accordance with the invention of fabricating the layers for a MOSFET of the kind described above with a doped silicon source layer, a doped polycrystalline silicon gate layer and a doped silicon drain layer is practiced by incorporating in individual layers, namely a drain layer, a gate layer and a source layer, after their fabrication, an additional electrically inert material, preferably carbon, to the source layer and/or the drain layer and/or the gate layer, in a concentration between 10¹⁸ cm⁻³ and 10²¹ cm⁻³ with the thus introduced relative change in the lattice constant being less than 5·10⁻³.

Where carbon is implanted, substantially the following process steps will be performed:

| | |
|---|---|
| A1 | fabrication of a pretreated doped substrate; |
| B1 | application of a thin thermal oxide layer on the substrate in a |
| | thickness between 3 and 10 nm; |
| C1 | precipitation of a polycrystalline silicon layer by a CVD process; |
| D1 | carbon enhancement by implantation in the gate layer; |
| E1 | annealing of implantation defects; |
| F1 | doping of the polycrystalline silicon gate layer; |
| G1 | structuring of the gate by etching of the polycrystalline silicon; |
| H1 | implanting carbon into the source and drain layers; |
| I1 | annealing of implantation defects; |
| K1 | doping of source and drain layers; and |
| L1 | fabrication of contact and wiring path systems. |

Alternatively, it is within the scope of the invention to add the carbon during the selective epitaxial growth of the source and drain layers. This would substantially be accomplished by the following process steps:

| | |
|---|---|
| A2 | fabrication of a pretreated doped substrate; |
| B2 | application of a thin thermal oxide layer on the substrate in a |
| | thickness between 3 and 10 nm; |
| C2 | precipitation of a polycrystalline silicon layer by a CVD process; |
| F2 | doping of the polycrystalline silicon gate layer; |
| G2 | structuring of the gate by etching of the polycrystalline silicon; |
| M2 | covering of the gate layer by application of an oxide layer; |
| N2 | structuring of the oxide layer; |
| O2 | selective epitaxy of the doped source and drain layers with the |
| | addition of carbon; |
| L2 | fabrication of contact and wiring path systems. |

For executing the method, during fabrication of the gate layer, the source layer and the drain layer, at least one of these layers is doped with boron in a concentration between 10²⁰ cm⁻³ and 10²¹ cm⁻³.

### DESCRIPTION OF THE SEVERAL DRAWINGS

The novel features which are considered to be characteristic of the invention are set forth with particularity in the appended claims. The invention itself, however, in respect of its structure, construction and lay-out as well as manufacturing techniques, together with other objects and advantages thereof, will be best understood from the following description of preferred embodiments when read in connection with the appended drawings, in which:

FIG. 1 is a schematic section through a MOSFET;

FIG. 2 depicts method steps for fabricating the layers of the MOSFET;

FIG. 3 depicts method steps for fabricating the layers of the MOSFET.

### DETAILED DESCRIPTION OF PREFERRED EMBODIMENTS

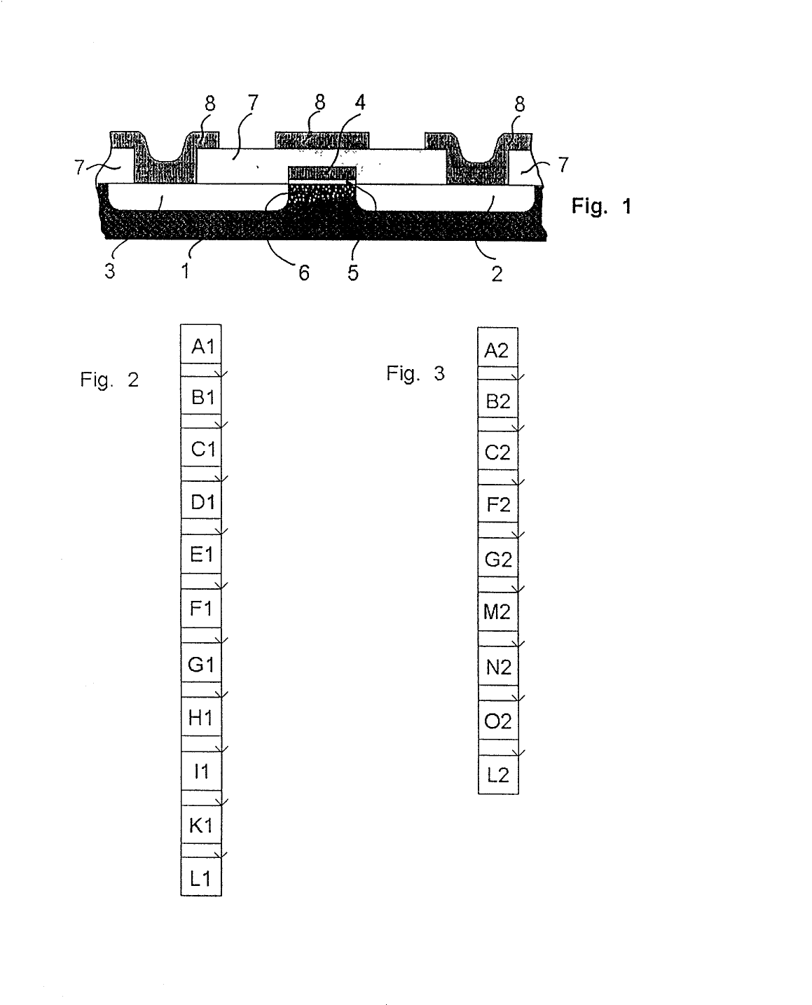

FIG. 1 is a schematic sectional view of a MOSFET provided with a drain layer 2, a source layer 3 and a p-doped gate layer 4. The transistor is additionally provided with a silicon substrate 1, a gate oxide layer 5, a p-channel 6, silicon oxide 7 and a contact and wiring path system 8. At least one of the three layers, namely the drain layer 2, source layer 3 or gate layer 4, contains carbon in a concentration of between 10¹⁸ cm⁻³ and 10²¹ cm⁻³. The polycrystalline silicon gate layer 4 is doped with boron in a concentration of between 10²⁰ cm⁻³ and 10²¹ cm⁻³. Such a transistor is fabricated by the method steps depicted in FIG. 2. Initially, B1, a thermal oxide layer of silicon oxide SiO₂ of a thickness of 5 nm is applied to a pretreated p⁺-doped silicon substrate A1, and a polycrystalline silicon layer is precipitated by a CVD process C1. This silicon layer has a thickness of 100 nm and forms the gate layer 4. Thereafter, carbon is implanted D1 in the gate layer 4 in a concentration of 5·10¹⁹ cm⁻³ and any implantation defects are subsequently annealed E1. The annealing process lasts 30 seconds at a constant temperature of 950° C. The thus introduced change in the lattice is less than 5·10⁻³. Thereafter, the polycrystalline silicon layer 4 is doped F1 with boron fluoride BF₂, and the polycrystalline silicon is subjected to etching, for instance by plasma etching G1. The concentration of the dopant in the MOSFET of the invention is 5·10²⁰ cm⁻³. Prior to doping K1 of the source layer 3 and the drain layer 2, carbon is also incorporated H1 in these layers in a concentration of 5·10¹⁹ cm⁻³ and any occurring defects are annealed I1 at a temperature of 950° C.

Thereafter, the contact and wiring path system 8 is structured L1. In the present example, step L1 is carried out by a dry etching method so that upon completion a salicide (=self aligned silicide) contact and wiring path system of 70 nm thickness will have been created.

An alternative method in accordance with the invention is schematically depicted in the block diagram of FIG. 3. Similar to the process already described, a thin thermal oxide is applied, B2, to a pretreated p⁺-doped substrate A2, and a polycrystalline silicon layer of about 100 nm thickness is precipitated by a CVD process, C2. The resultant layer of silicon oxide SiO₂ has a thickness of 5 nm. The polycrystalline silicon gate layer is now doped, F2, with boron fluoride BF₂ and structured by plasma etching G2. After doping, the concentration of boron in the gate layer of the inventive MOSFET amounts to 5·10²⁰ cm⁻³. The gate layer is covered, M2, by an oxide layer of about 50 nm thickness which is structured as well. Structuring of the protective oxide is carried on by plasma etching. Thereafter, a selective epitaxial precipitation, O2, of the doped source and drain layers with carbon added during the epitaxy phase is carried out, which is followed by the source and drain regions being doped with boron in a concentration of 5·10²⁰ cm⁻³. Fabrication L2 of the contact and wire path systems is carried out as in the previously described process. Accordingly, in this embodiment, structuring of the contact and wire path system is also performed by a dry etching process, and the MOSFET in accordance with the invention will be provided with a salicide contact and wire path system layer of 70 nm thickness.

In the present invention, a MOSFET and a method of fabricating the layers of such a transistor have been described on the basis of concrete embodiments. It is, however, to be noted that the present invention is not limited to the details of the description of embodiments as alterations and alternatives are claimed within the scope of the patent claims.

What is claimed is:

1. A method of fabricating a metal-oxide semiconductor field-effect transistor (MOSFET), comprising the steps of:
providing a pretreated doped substrate;
forming a thin oxide layer on the substrate;
forming a polycrystalline silicon gate layer by chemical vapor deposition (CVD);
doping the polycrystalline silicon gate layer and structuring a gate therein by etching;
covering the gate layer with a protective layer;
structuring the protective layer;
forming at least one of a boron doped source layer and a boron doped drain layer;
incorporating carbon in a concentration of from about 10¹⁸ cm⁻³ to about 10²¹ cm⁻³ in at least one of the gate layer, source layer and drain layer; and
fabricating contact and wiring path systems.

2. The method of claim 1, wherein the gate layer is doped with boron at a concentration of from about 10²⁰ cm⁻³ to about 10²¹ cm⁻³ and wherein carbon is added to the gate layer at a concentration from about 1*10²⁰ cm⁻³ to about 5*10²⁰ cm⁻³.

3. The method of claim 2, wherein the gate layer is doped with boron fluoride BF₂.

4. The method of claim 1, wherein the silicon source layer is doped with boron at a concentration of from about 10²⁰ cm⁻³ to about 10²¹ cm⁻³.

5. The method of claim 1, wherein the silicon drain layer is doped with boron at a concentration of from about 10²⁰ cm⁻³ to about 10²¹ cm⁻³.

6. The method of claim 1, further including the step of annealing the gate layer.

7. The method of claim 7, wherein the step of annealing is performed for about 30 seconds at a temperature of about 950° C.

8. The method of claim 1, wherein at least one of the drain layer and the source layer is formed by epitaxial growth with carbon being added during the epitaxy phase.

9. A MOSFET provided with a doped silicon source layer, a doped polycrystalline gate layer and a doped silicon drain layer having a predetermined lattice constant and comprising:
in at least one of the source layer, gate layer and drain layer an electrically inert material in a concentration of from about 10¹⁸ cm⁻³ to about 10²¹ cm⁻³ thereby changing the lattice constant by less than 0.005 in the at least one layer.

10. The MOSFET of claim 9, wherein the electrically inert material is carbon and the concentration thereof is from about 1*10²⁰ cm⁻³ to about 5*10²⁰ cm⁻³.

11. The MOSFET of claim 10, wherein at least one of the silicon source layer, polycrystalline gate layer and silicon drain layer is doped with boron at a concentration of from about 10²⁰ cm⁻³ to about 10²¹ cm⁻³.

11. The MOSFET of claim 9, wherein the gate layer is doped with boron at a concentration of from about 10²⁰ cm⁻³ to about 10²¹ cm⁻³ and has a carbon content in a concentration from about 1*10²⁰ cm⁻³ to about 5*10²⁰ cm⁻³.

11. The MOSFET of claim 9, wherein the silicon source layer is doped with boron at a concentration of from about 10²⁰ cm⁻³ to about 10²¹ cm⁻³.

12. The MOSFET of claim 9, wherein the silicon drain layer is doped with boron at a concentration of from about 10²⁰ cm⁻³ to about 10²¹ cm⁻³.

13. The MOSFET of claim 9, wherein at least one of the source layer and drain layer has a carbon content in a concentration of from about 1*10²⁰ cm⁻³ to about 5*10²⁰ cm⁻³.
